(19) United States
(12) Patent Application Publication
(10) Pub. No.: US 2011/0032128 A1
(43) Pub. Date: Feb. 10, 2011

(54) ANALOG-DIGITAL CONVERTER CIRCUIT AND CALIBRATION METHOD

(75) Inventors: Akemi WATANABE, Kanagawa (JP); Yuji NAKAJIMA, Kanagawa (JP)

Correspondence Address: YOUNG & THOMPSON, 209 Madison Street, Suite 500, Alexandria, VA, 22314, US

(73) Assignee: NEC ELECTRONICS CORPORATION, Kanagawa (JP)

(21) Appl. No.: 12/827,244

(22) Filed: Jun. 30, 2010

(30) Foreign Application Priority Data
Aug. 7, 2009 (JP) 2009-185104

(51) Int. Cl. H03M 1/10

(52) U.S. Cl. 341/120

(57) ABSTRACT

Provided is an analog-digital converter circuit having a normal mode for converting a received analog signal into a digital signal, and a calibration mode for adjusting an offset voltage of a comparator, the analog-digital converter including: a first comparator having a first analog signal input terminal supplied with an analog signal, and a first reference signal input terminal supplied with a first reference signal, in the normal mode; and a first calibration circuit that adjusts an offset voltage of the first comparator. In the calibration mode, assuming that a calibration resolution of the first calibration circuit is Δ₁, a potential difference between a reference signal supplied to the first analog signal input terminal and a reference signal supplied to the first reference signal input terminal is n₁Δ₁+Δ₁/2 (where n₁ is an integer).

### INCORPORATION BY REFERENCE

This application is based upon and claims the benefit of priority from Japanese patent application No. 2009-185104, filed on Aug. 7, 2009, the disclosure of which is incorporated herein in its entirety by reference.

### BACKGROUND

1. Field of the Invention

The present invention relates to an analog-digital converter circuit and a calibration method. In particular, the present invention relates to an analog-digital converter circuit including a calibration circuit that adjusts an offset voltage of a comparator, and to a method of adjusting an offset voltage of a comparator.

2. Description of Related Art

A typical analog-digital (A/D) converter circuit includes a comparator for converting an analog signal into a digital signal. Such a comparator has an offset voltage caused by manufacturing variations. As the offset voltage increases, the accuracy of the A/D converter decreases. U.S. Pat. No. 7,075,465 and Japanese Unexamined Patent Application Publication Nos. 2002-319863, 10-65542, and 08-279752 (the specification of U.S. Pat. No. 5,696,508) each disclose an analog-digital converter circuit including a calibration circuit that adjusts an offset voltage of a comparator.

In analog-digital converter circuits disclosed in the above-mentioned related arts, assuming that the calibration circuit for adjusting an offset voltage of a comparator has a calibration resolution A, an adjusted offset voltage falls within the range of 0 to Δ.

### SUMMARY

The present inventor has found a problem that it is impossible for analog-digital converter circuits disclosed in the above-mentioned related arts to set the upper limit of an adjusted offset voltage to be smaller than a calibration resolution A.

A first exemplary aspect of the present invention is an analog-digital converter circuit having a normal mode for converting a received analog signal into a digital signal, and a calibration mode for adjusting an offset voltage of a comparator, the analog-digital converter including: a first comparator having a first analog signal input terminal supplied with an analog signal, and a first reference signal input terminal supplied with a first reference signal, in the normal mode; and a first calibration circuit that adjusts an offset voltage of the first comparator. In the calibration mode, assuming that a calibration resolution of the first calibration circuit is Δ₁, a potential difference between a reference signal supplied to the first analog signal input terminal and a reference signal supplied to the first reference signal input terminal is n₁Δ₁+Δ₁/2 (where n₁ is an integer).

A second exemplary embodiment of the present invention is an analog-digital converter circuit having a normal mode for converting a received analog signal into a digital signal, and a calibration mode for adjusting an offset voltage of a comparator, the analog-digital converter circuit including: a first comparator having a first analog signal input terminal supplied with an analog signal, and a first reference signal input terminal supplied with a first reference signal, in the normal mode; and a first calibration circuit that adjusts an offset voltage of the first comparator. The first calibration circuit includes: a first main calibration unit that adjusts an offset adjustment amount so that an adjusted offset voltage has a value in a range of 0 to Δ₁ (where Δ₁ is a calibration resolution of the first calibration circuit); and a first fine adjustment unit that shifts the offset adjustment amount by Δ₁/2.

A third exemplary embodiment of the present invention is a calibration method that adjusts an offset voltage of a comparator by a calibration circuit having a calibration resolution Δ, the calibration method including: fixing a potential difference applied to two input terminals of the comparator to nΔ+Δ/2 (where n is an integer); changing a calibration signal supplied to the comparator from the calibration circuit; and determining an offset adjustment amount based on an output signal output from the comparator.

A fourth exemplary embodiment of the present invention is a calibration method that adjusts an offset voltage of a comparator by a calibration circuit having a calibration resolution Δ, the calibration method including: causing two input terminals of the comparator to be short-circuited; changing a calibration signal supplied to the comparator from the calibration circuit; determining an offset adjustment amount based on an output signal output from the comparator; and shifting the determined offset adjustment amount by Δ/2.

The present invention can provide a highly accurate analog-digital converter circuit by determining an offset adjustment amount assuming that a potential between input terminals of a comparator is nΔ+Δ/2 (where n is an integer), or by shifting the determined offset adjustment amount by Δ/2 after the offset adjustment amount is determined.

According to exemplary aspects of the present invention, it is possible to provide a highly accurate analog-digital converter circuit capable of setting the upper limit of an adjusted offset voltage to be smaller than a calibration resolution Δ of a calibration circuit.

### BRIEF DESCRIPTION OF THE DRAWINGS

The above and other exemplary aspects, advantages and features will be more apparent from the following description of certain exemplary embodiments taken in conjunction with the accompanying drawings, in which:

FIG. 1 is a circuit diagram showing an A/D converter according to a first exemplary embodiment of the present invention;

FIG. 2A is a circuit diagram showing an example of a switch SW;

FIG. 2B is a diagram showing exemplary connection states of the switch SW in a normal mode;

FIG. 2C is a diagram showing an exemplary connection state of the switch SW in a calibration mode;

FIG. 3 is a diagram showing a function model of a comparator CMP shown in FIG. 1;

FIG. 4 is a circuit diagram showing specific examples of the comparator CMP and a digital-analog converter DAC according to the first exemplary embodiment;

FIG. 5 is a flowchart showing a calibration method according to the first exemplary embodiment;

FIG. 6 is a graph illustrating the calibration method according to the first exemplary embodiment;

FIG. 7 is a table showing offset voltages OFF, final calibration voltages Vcalf, and final adjusted offset voltages OFFadjf of the comparator CMP according to the first exemplary embodiment;

FIG. 8 is a graph showing variations of the final adjusted offset voltage OFFadjf and a final calibration input signal A1f with respect to the offset voltage OFF of the comparator CMP according to the first exemplary embodiment;

FIG. 9 is a diagram showing a function model of a comparator CMP according to a comparative example of the first exemplary embodiment;

FIG. 10 is a flowchart showing a calibration method according to the comparative example of the first exemplary embodiment;

FIG. 11 is a graph illustrating the calibration method according to the comparative example of the first exemplary embodiment;

FIG. 12 is a table showing offset voltages OFF, final calibration voltages Vcalf, and final adjusted offset voltages OFFadjf of the comparator CMP according to the comparative example of the first exemplary embodiment;

FIG. 13 is a graph showing variations of the final adjusted offset voltage OFFadjf and a final calibration input signal A1f with respect to the offset voltage OFF of the comparator CMP according to the comparative example of the first exemplary embodiment;

FIG. 14 schematically shows an output of the comparator CMP when an input of the comparator CMP includes no offset voltage and an output of the comparator CMP when an input of the comparator CMP includes an offset voltage;

FIG. 15 is a circuit diagram showing an A/D converter according to a second exemplary embodiment of the present invention;

FIG. 16 is a circuit diagram showing an A/D converter according to a comparative example of the second exemplary embodiment;

FIG. 17 is a conceptual diagram showing 4-bit binary search;

FIG. 18 is a graph illustrating a process of 4-bit binary search according to a third exemplary embodiment of the present invention;

FIG. 19 is a graph illustrating a process of 4-bit binary search according to a comparative example of the third exemplary embodiment;

FIG. 20 is a flowchart showing a calibration method according to a fourth exemplary embodiment of the present invention;

FIG. 21A is a graph corresponding to (A) in step ST12 shown in FIG. 20;

FIG. 21B is a graph corresponding to (B) in step ST12 shown in FIG. 20;

FIG. 21C is a graph corresponding to (C) in step ST12 shown in FIG. 20;

FIG. 22 is a circuit diagram showing specific examples of a comparator CMP and a digital-analog converter DAC according to a fifth exemplary embodiment of the present invention;

FIG. 23 is a circuit diagram showing a parallel A/D converter according to a sixth exemplary embodiment of the present invention;

FIG. 24 is a circuit diagram showing a parallel A/D converter according to a seventh exemplary embodiment of the present invention;

FIG. 25A is a diagram schematically showing a connection state in a normal mode according to the seventh exemplary embodiment; and

FIG. 25B is a diagram schematically showing a connection state in a normal mode according to the sixth exemplary embodiment.

### DETAILED DESCRIPTION OF THE EXEMPLARY EMBODIMENTS

Exemplary embodiments of the present invention will be described in detail below with reference to the drawings. The present invention is not limited to the exemplary embodiments described below. To clarify the explanation, the following description and the drawings are abbreviated or simplified as appropriate.

### First Exemplary Embodiment

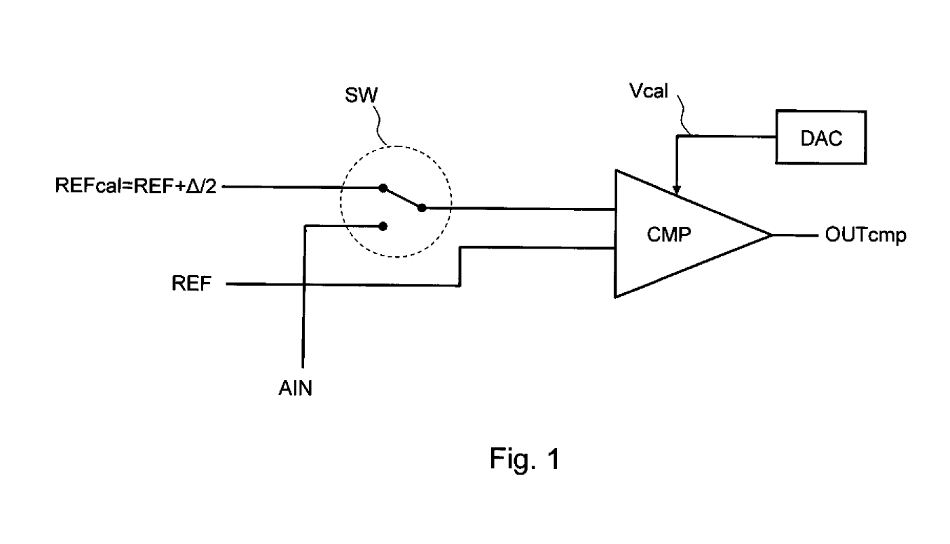

Referring to FIGS. 1 to 14, a first exemplary embodiment of the present invention will be described. FIG. 1 is a circuit diagram showing an A/D converter according to the first exemplary embodiment. The A/D converter includes a comparator CMP, a digital-analog converter DAC, and a switch SW.

In a normal mode for performing a normal operation, the comparator CMP receives an analog input signal AIN at one input terminal, and also receives a reference voltage REF at the other input terminal. The reference voltage is a ground potential 0 V, for example. The comparator CMP binarizes the analog input signal AIN to “1 (H: High)” or “0 (L: Low)”, and outputs an output signal OUTcmp. In this case, the comparator CMP has an offset voltage caused due to production variations.

The digital-analog converter DAC is one embodiment of a calibration circuit for adjusting the offset voltage of the comparator CMP. The digital-analog converter DAC generates a calibration voltage Vcal based on a digital control signal. Assume herein that the resolution of the digital-analog converter DAC is Δ.

The switch SW is a switch that switches between the normal mode and a calibration mode for adjusting the offset voltage of the comparator CMP. In the normal mode, the analog input signal AIN is input to one input terminal of the comparator CMP through the switch SW. Meanwhile, in the calibration mode, a calibration reference voltage REFcal=REF+Δ/2 is input to one input terminal of the comparator CMP through the switch SW.

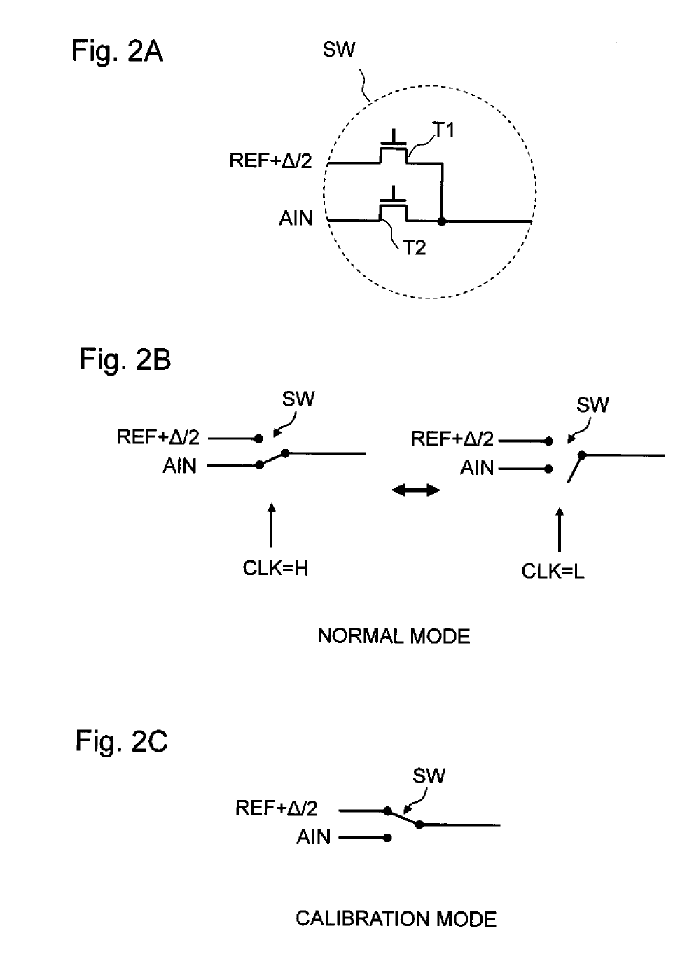

FIG. 2A is a circuit diagram showing an example of the switch SW. Referring to FIG. 2A, the switch SW includes two MOS transistors T1 and T2. One of the source and drain of the MOS transistor T1 is connected to the calibration reference voltage REF-FΔ/2. One of the source and drain of the MOS transistor T2 is connected to the analog input signal AIN. The other of the source and drain of each of the MOS transistors T1 and T2 is connected to one input terminal of the comparator CMP. A control signal input to the gate terminal of each of the MOS transistors T1 and T2 controls ON/OFF of the transistors T1 and T2. Both a PMOS transistor and an NMOS transistor may be used as the transistors T1 and T2.

FIG. 2B is a diagram showing exemplary connection states of the switch SW in the normal mode. A clock signal CLK is supplied to the gate of the MOS transistor T2. Meanwhile, in the normal mode, the MOS transistor T1 is always off. When the MOS transistor T2 is an NMOS transistor, for example, and when the clock signal CLK is at high level (CLK=H) as shown in FIG. 2B, the MOS transistor T2 turns on and the analog input signal AIN is sampled. Meanwhile, when the clock signal CLK is at low level (CLK=L), the MOS transistor T2 turns off and the sampled analog input signal AIN is held. In such a configuration, the MOS transistor T2 functions as a switch as well as a sample-and-hold circuit.

FIG. 2C is a diagram showing an exemplary connection state of the switch SW in the calibration mode. For example, an enable signal (not shown) in the calibration mode is supplied to the gate terminal of the MOS transistor T1. Thus, the MOS transistor T1 turns on in the calibration mode. Meanwhile, the MOS transistor T2 is always off in the calibration mode.

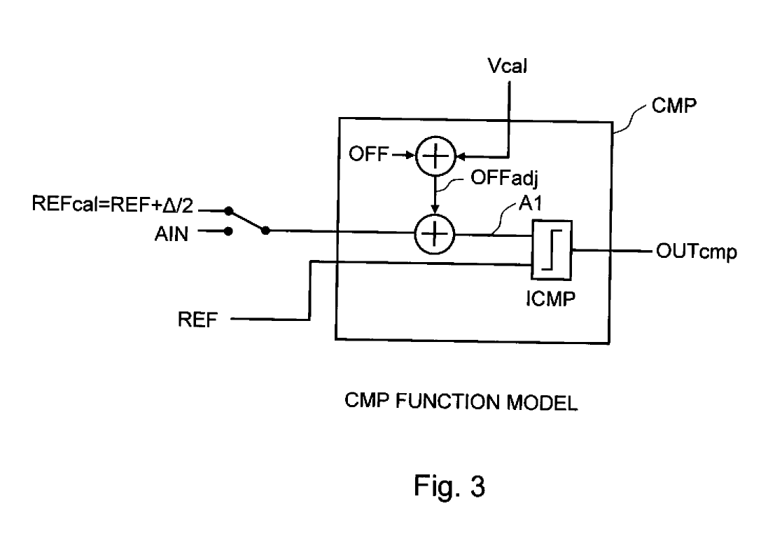

FIG. 3 is a diagram showing a function model of the comparator CMP shown in FIG. 1. As shown in FIG. 3, in this function model, the comparator CMP includes an ideal comparator ICMP and has an offset voltage OFF therein. In the calibration mode, an adjusted offset voltage OFFadj is generated by adding the offset voltage OFF to the calibration voltage Vcal output from the digital-analog converter DAC.

Further, a calibration input signal A1 is generated by adding the adjusted offset voltage OFFadj to the calibration reference voltage REFcal=REF+Δ/2. The calibration input signal A1 is input to one input terminal of the ideal comparator ICMP. The reference voltage REF is input to the other input terminal of the ideal comparator ICMP. Based on the output signal OUTcmp from the ideal comparator ICMP, the calibration voltage Vcal for compensating for the offset voltage OFF, i.e., for setting the adjusted offset voltage OFFadj to be as close to 0 V as possible can be determined.

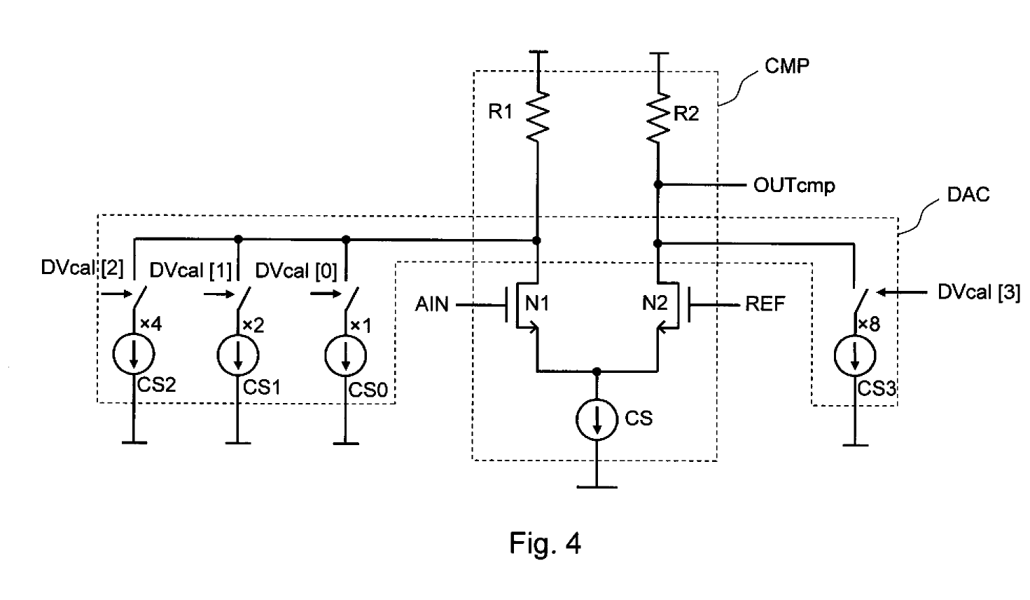

FIG. 4 is a circuit diagram showing specific examples of the comparator CMP and the digital-analog converter DAC according to the first exemplary embodiment. The comparator CMP includes load resistors R1 and R2, NMOS transistors N1 and N2, and a current source CS. One end of each of the load resistors R1 and R2 is connected to a power supply. The other end of the load resistor R1 is connected to the drain of the NMOS transistor N1. The other end of the load resistor R2 is connected to the drain of the NMOS transistor N2. The sources of the NMOS transistors N1 and N2 are connected to one end of the current source CS. The other end of the current source CS is grounded. The gates of the NMOS transistors N1 and N2 are supplied with the analog input signal AIN and the reference voltage REF, respectively. The output signal OUTcmp is output from a node between the load resistor R2 and the NMOS transistor N2.

The digital-analog converter DAC includes four current sources CS0, CS1, CS2, and CS3. Assuming that the amount of current generated by the current source CS0 is 1, the amounts of current generated by the current sources CS1, CS2, and CS3 are 2, 4, and 8, respectively. One end of each of the four current sources CS0, CS1, CS2, and CS3 is grounded. The other end of each of the three current sources CS0, CS1, and CS2 is connected to a node between the load resistor R1 and the NMOS transistor N1 through respective switches. The other end of the current source CS3 is connected to a node (output node) between the load resistor R2 and the NMOS transistor N2 through a switch.

As shown in FIG. 4, ON/OFF of the switches respectively connected to the four current sources CS0, CS1, CS2, and CS3 is controlled by 4-bit digital control signals DVcal[0] to DVcal[3]. The digital control signals DVcal[0] to DVcal[3] are binary signals represented in two's complement. Assuming that the resolution of the digital-analog converter DAC is A, when DVcal[3]=1 (i.e., H), the calibration voltage Vcal is in the range of −8Δ to −Δ. When DVcal[3]=0 (i.e., L), the calibration voltage Vcal is in the range of 0 to 7Δ. Thus, the calibration voltage Vcal having 16 levels of −8Δ to 7Δ can be generated according to the digital control signals DVcal.

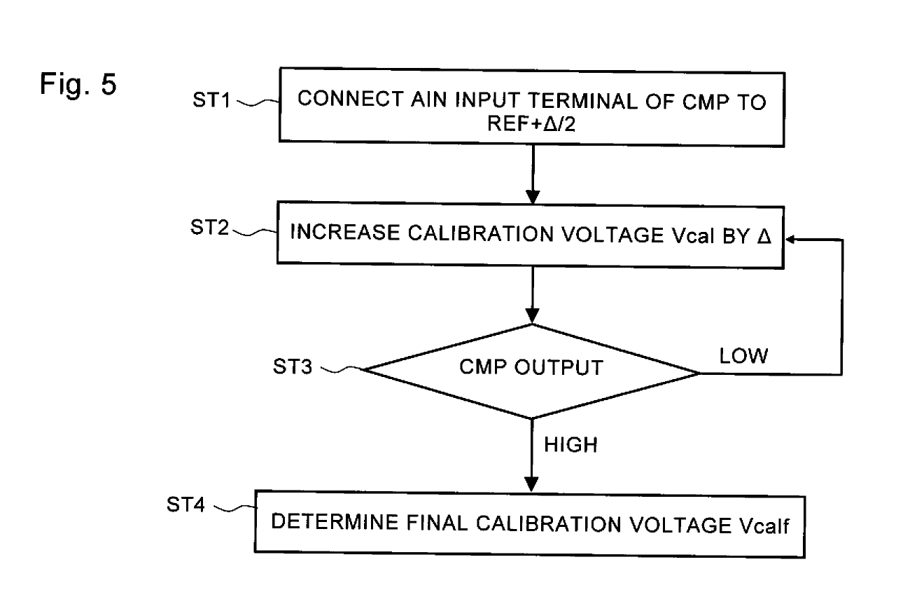

Referring next to FIG. 5, a calibration method will be described. FIG. 5 is a flowchart showing a calibration method according to the first exemplary embodiment. First, the input terminal for the analog input signal AIN of the comparator CMP is connected to the calibration reference voltage REFcal=REF+Δ/2 (ST1). Next, the calibration voltage Vcal output from the digital-analog converter DAC is increased by Δ from a start potential which is the lowest potential (ST2). Then, when the output of the comparator CMP is L (Low), the process returns to step ST2, and the calibration voltage Vcal is further increased by Δ (Low in ST3). That is, this process is repeated until the output of the comparator CMP becomes H (High). After the output of the comparator CMP becomes H (High), the final calibration voltage Vcalf is determined and the calibration is completed (ST4).

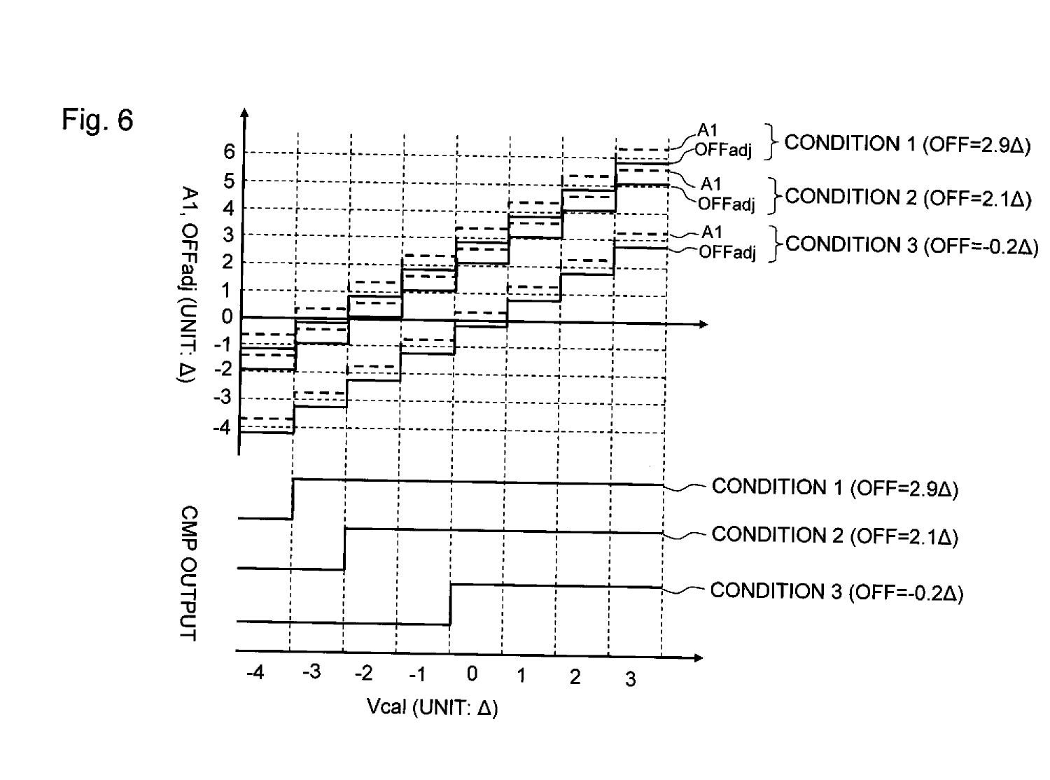

Referring now to FIG. 6, a specific example will be described. The reference voltage REF is set to 0 V (REF=0 V), because the generality is not lost even when the reference voltage REF is equal to 0 V. The horizontal axis of FIG. 6 represents the calibration voltage Vcal output from the digital-analog converter DAC in units of the resolution Δ of the digital-analog converter DAC. The longitudinal axis in the upper portion of FIG. 6 represents the adjusted offset voltage OFFadj and the calibration input signal A1 in units of the resolution Δ of the digital-analog converter DAC. In this case, OFFadj=OFF+Vcal, or A1=OFFadj+Δ/2 is satisfied. The longitudinal axis in the lower portion of FIG. 6 represents the output of the comparator CMP. As described above, the comparator CMP compares the calibration input signal A1 with the reference voltage REF=0 V.

FIG. 6 shows three exemplary conditions which differ from each other in the offset voltage OFF of the comparator CMP. Condition 1 is OFF=2.9Δ, Condition 2 is OFF=2.1Δ, and Condition 3 is OFF=−0.2Δ.

Condition 1 (OFF=2.9Δ) is described in detail below. When the calibration voltage Vcal is −4Δ, OFFadj=2.9Δ−4Δ=−1.1Δ, and thus, A1=−1.1Δ+Δ/2=−0.6Δ. Accordingly, when the calibration voltage Vcal≦−4Δ, the output of the comparator CMP is L. When the calibration voltage Vcal is −3Δ, OFFadj=2.9Δ−3Δ=−0.1Δ, and thus, A1=−0.1Δ+Δ/2=0.4Δ. Accordingly, the output of the comparator CMP switches to H, and the calibration is completed. In Condition 1, the final calibration voltage Vcalf=−3Δ, and a final adjusted offset voltage OFFadjf=2.9Δ−3Δ=−0.1Δ. That is, −Δ/2<OFFadjf≦Δ/2.

Condition 2 (OFF=2.1Δ) is described in detail below. When the calibration voltage Vcal is −3Δ, OFFadj=2.1Δ−3Δ=−0.9Δ, and thus, A1=−0.9Δ+Δ/2=−0.4Δ. Accordingly, when the calibration voltage Vcal≦−3Δ, the output of the comparator CMP is L. When the calibration voltage Vcal is −2Δ, OFFadj=2.1Δ−2Δ=0.1Δ, and thus, A1=0.1Δ+Δ/2=0.6Δ. Accordingly, the output of the comparator CMP switches to H, and the calibration is completed. Therefore, in Condition 2, the final calibration voltage Vcalf=2Δ, and the final adjusted offset voltage OFFadjf=2.1Δ−2Δ=0.1Δ. That is, −Δ/2<OFFadjf≦Δ/2.

Condition 3 (OFF=−0.2Δ) is described in detail below. When the calibration voltage Vcal is −Δ, OFFadj=−0.2Δ−1Δ=−1.2Δ, and thus, A1=−1.2Δ+Δ/2=−0.7Δ. Accordingly, when calibration voltage Vcal≦−Δ, the output of the comparator CMP is L. When the calibration voltage Vcal is 0Δ, OFFadj=−0.2Δ+0Δ=−0.2Δ, and thus, A1=−0.2Δ+Δ/2=0.3Δ. Accordingly, the output of the comparator CMP switches to H, and the calibration is completed. Therefore, in Condition 3, the final calibration voltage Vcalf=0Δ, and final adjusted offset voltage OFFadjf=−0.2Δ+0Δ=−0.2Δ. That is, −Δ/2<OFFadjf≦Δ/2.

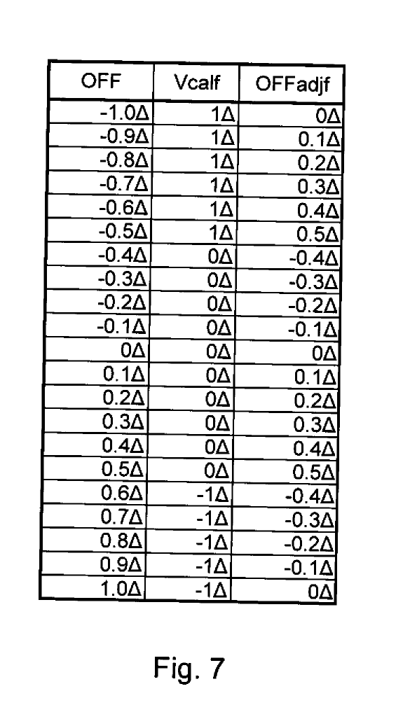

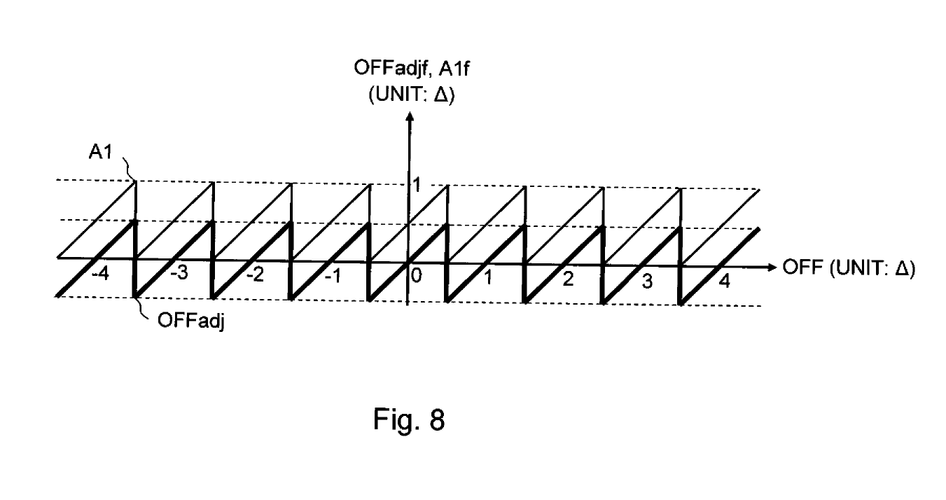

FIG. 7 shows a table illustrating the final calibration voltages Vcalf and the final adjusted offset voltages OFFadjf when the offset voltage OFF of the comparator CMP satisfies −1.0≦ΔOFF≦1.0. FIG. 8 shows a graph having a horizontal axis representing the offset voltage OFF of the comparator CMP (in units of Δ), and a longitudinal axis representing the final adjusted offset voltage OFFadjf and a final calibration input signal A1f. As shown in FIGS. 7 and 8, the final adjusted offset voltage OFFadjf satisfies −Δ/2<OFFadjf≦Δ/2. As shown in FIG. 8, this is obtained by shifting the calibration input signal A1 and the adjusted offset voltage OFFadj, which are compared by the comparator CMP in the calibration mode, by Δ/2.

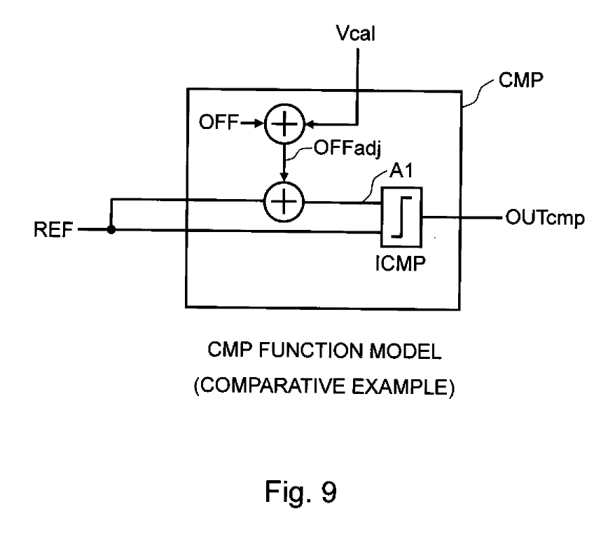

FIG. 9 is a diagram showing a function model of a comparator CMP according to a comparative example of the first exemplary embodiment. The function model shown in FIG. 9 differs from the function model of the comparator CMP according to the first exemplary embodiment shown in FIG. 3 in that the input terminals of the comparator CMP are short-circuited and are supplied with the reference voltage REF in the calibration mode. The other components are the same, so the description thereof is omitted.

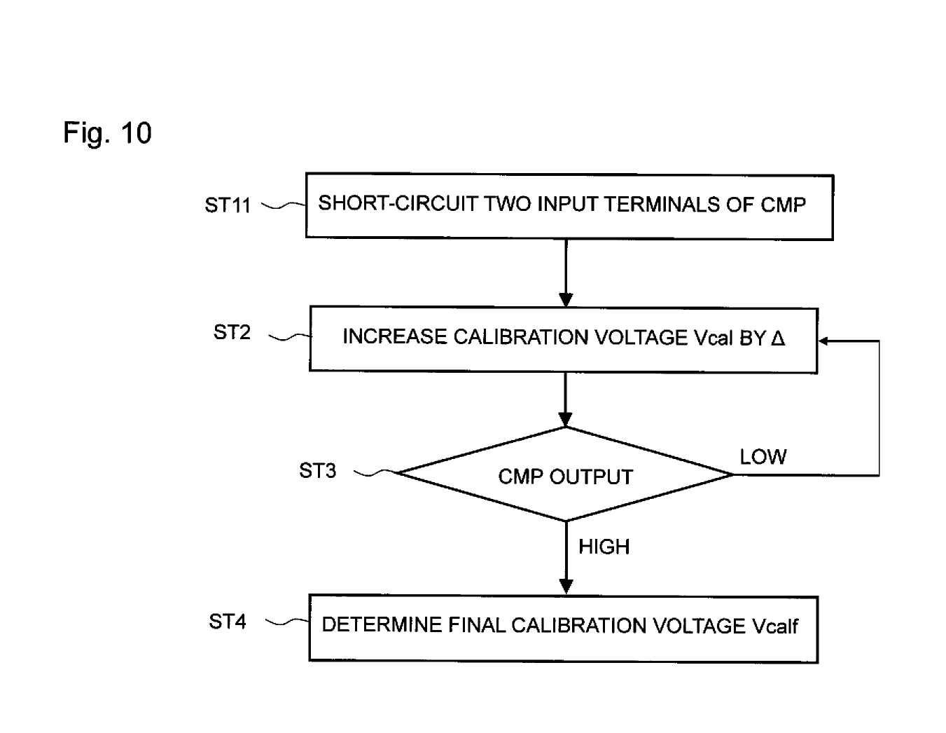

Referring next to FIG. 10, a calibration method according to the comparative example will be described. FIG. 10 is a flowchart showing the calibration method according to the comparative example of the first exemplary embodiment. First, the two input terminals of the comparator CMP are short-circuited (ST11). Next, the calibration voltage Vcal output from the digital-analog converter DAC is increased by A from the lowest potential (ST2). Then, when the output of the comparator CMP is L (Low), the process returns to step ST2, and the calibration voltage Vcal is further increased by A (Low in ST3). That is, this process is repeated until the output of the comparator CMP becomes H (High). When the output of the comparator CMP becomes H (High), the final calibration voltage Vcalf is determined and the calibration is completed (ST4). In short, steps ST2 to ST4 are the same as those in the flow of the calibration method according to the first exemplary embodiment shown in FIG. 5.

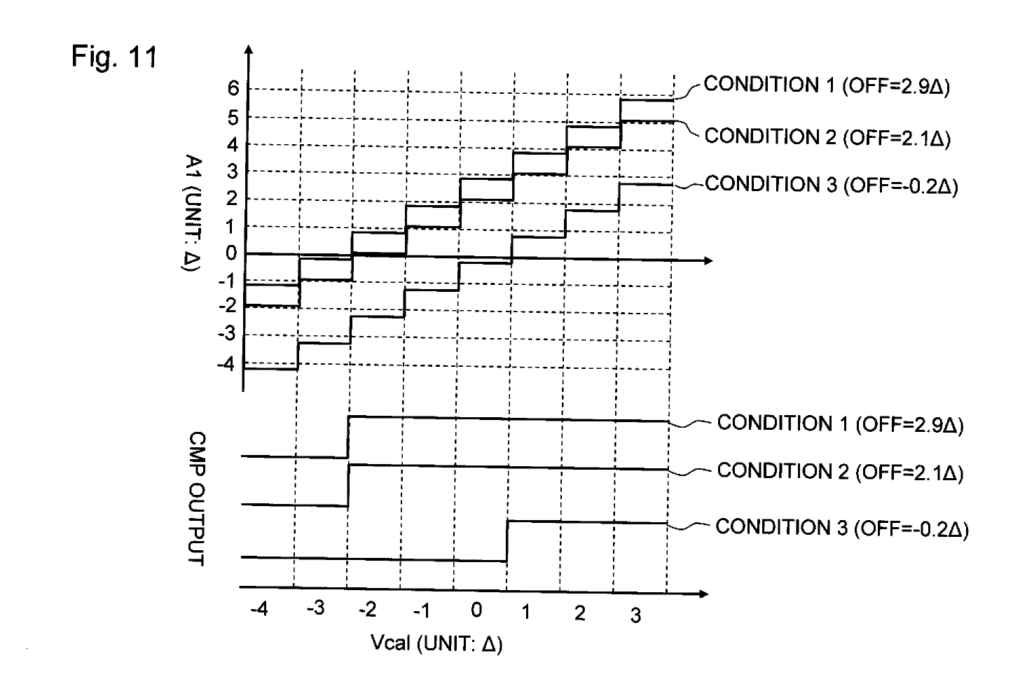

Referring now to FIG. 11, a specific example will be described. As described above with reference to FIG. 6, the reference voltage REF is set to 0 V (REF=0 V), because the generality is not lost even when the reference voltage REF is equal to 0 V. Similar to FIG. 6, the horizontal axis of FIG. 11 represents the calibration voltage Vcal output from the digital-analog converter DAC in units of the resolution Δ of the digital-analog converter DAC. The longitudinal axis in the upper portion of FIG. 11 represents the calibration input signal A1 in units of the resolution Δ of the digital-analog converter DAC. In this case, A1=OFFadj (adjusted offset voltage)=OFF+Vcal. The longitudinal axis in the lower portion of FIG. 11 represents the output of the comparator CMP. As described above, the comparator CMP compares the calibration input signal A1 with the reference voltage REF=0 V.

FIG. 11 shows three exemplary conditions which differ from each other in the offset voltage OFF of the comparator CMP. The three conditions are the same as those shown in FIG. 6. Condition 1 is OFF=2.9Δ, Condition 2 is OFF=2.1Δ, and Condition 3 is OFF=−0.2Δ.

Condition 1 (OFF=2.9Δ) is described in detail below. When the calibration voltage Vcal is −3Δ, A1=2.9Δ−3Δ=−0.1Δ, and thus, the output of the comparator CMP is L. When the calibration voltage Vcal is −2Δ, A1=2.9Δ−2Δ=0.9Δ, and thus, the output of the comparator CMP switches to H, and the calibration is completed. In Condition 1, the final calibration voltage Vcalf=2Δ, and the final adjusted offset voltage OFFadjf=2.9Δ−2Δ=0.9Δ. That is, 0<OFFadjf≦Δ.

Condition 2 (OFF=2.1Δ) is described in detail below. When the calibration voltage Vcal is −3Δ, A1=2.1Δ−3Δ=−0.9Δ, and thus, the output of the comparator CMP is L. When the calibration voltage Vcal is −2Δ, A1=2.1Δ−2Δ=0.1Δ. Accordingly, the output of the comparator CMP switches to H, and the calibration is completed. Therefore, in Condition 2, the final calibration voltage Vcalf=−2Δ, and the final adjusted offset voltage OFFadjf=2.1Δ−2Δ=0.1Δ. That is, 0<OFFadjf≦Δ.

Condition 3 (OFF=−0.2Δ) is described in detail below. When the calibration voltage Vcal is 0Δ, A1=−0.2Δ+0Δ=−0.2Δ, and thus, the output of the comparator CMP is L. When the calibration voltage Vcal is 1Δ, A1=−0.2Δ+1Δ=0.8Δ. Accordingly, the output of the comparator CMP switches to H, and the calibration is completed. Therefore, in Condition 3, the final calibration voltage Vcalf=1Δ, and the final adjusted offset voltage OFFadjf=−0.2Δ+1Δ=0.8Δ. That is, 0<OFFadjf≦Δ.

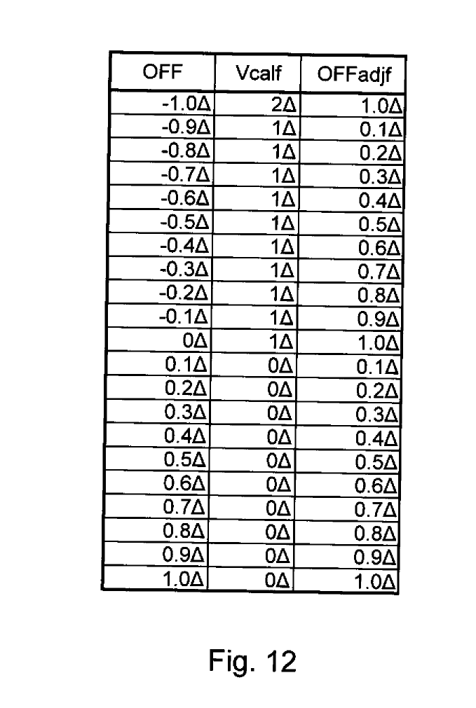

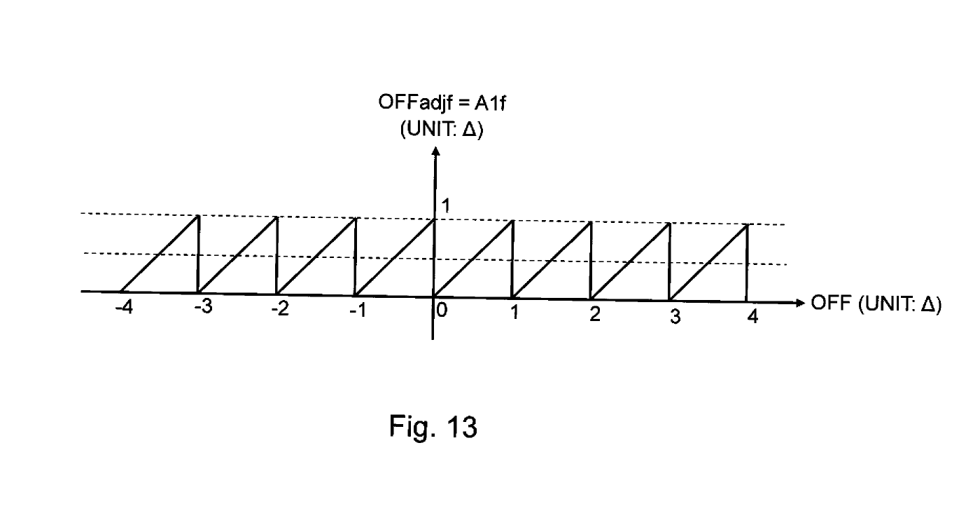

FIG. 12 shows a table illustrating the final calibration voltages Vcalf and the final adjusted offset voltages OFFadjf when the offset voltage OFF of the comparator CMP satisfies −1.0≦ΔOFF≦1.0. FIG. 13 shows a graph having a horizontal axis representing the offset voltage OFF of the comparator CMP (in units of Δ), and a longitudinal axis representing the final adjusted offset voltage OFFadjf (i.e., the final calibration input signal A1f). As shown in FIGS. 12 and 13, in the comparative example, the final adjusted offset voltage OFFadjf satisfies 0<OFFadjf≦Δ.

As described above, in the comparative example, the final adjusted offset voltage OFFadjf satisfies 0<OFFadjf≦Δ (Δ represents the resolution of the digital-analog converter DAC). It is known that when the analog-digital converter circuit includes multiple comparators, an average component of an offset (systematic offset) of the input/output characteristics of the analog-digital converter circuit causes deterioration in performance of a device. Thus, in order to eliminate the systematic offset, it is preferable to set an average value of the adjusted offset voltage of the comparator to be close to 0. In the comparative example, the average value of the offset voltage is theoretically equal to Δ/2.

Meanwhile, in the first exemplary embodiment, a potential difference between the inputs of the comparator CMP in the calibration mode is set to Δ/2. As a result, −Δ/2<OFFadjf≦Δ/2 is satisfied with respect to the final adjusted offset voltage OFFadjf. In short, the absolute value of the final adjusted offset voltage OFFadjf can be halved without changing the resolution Δ of the digital-analog converter DAC. Therefore, a more accurate A/D converter can be provided. It is most preferable to set the potential difference between the inputs of the comparator CMP in the calibration mode to Δ/2. Alternatively, if the input potential difference is set to n t+Δ/2 (where n is an integer), the same effects can be obtained. This is because “nΔ” can be recovered logically after the calibration operation.

In a parallel A/D converter including multiple combinations of the comparator CMP and the digital-analog converter DAC according to the first exemplary embodiment, −Δ/2<OFFadjf≦Δ/2 is satisfied for each comparator CMP. Further, the average value of the offset voltage can be theoretically set to 0. Therefore, a highly accurate A/D converter having no systematic offset can be provided.

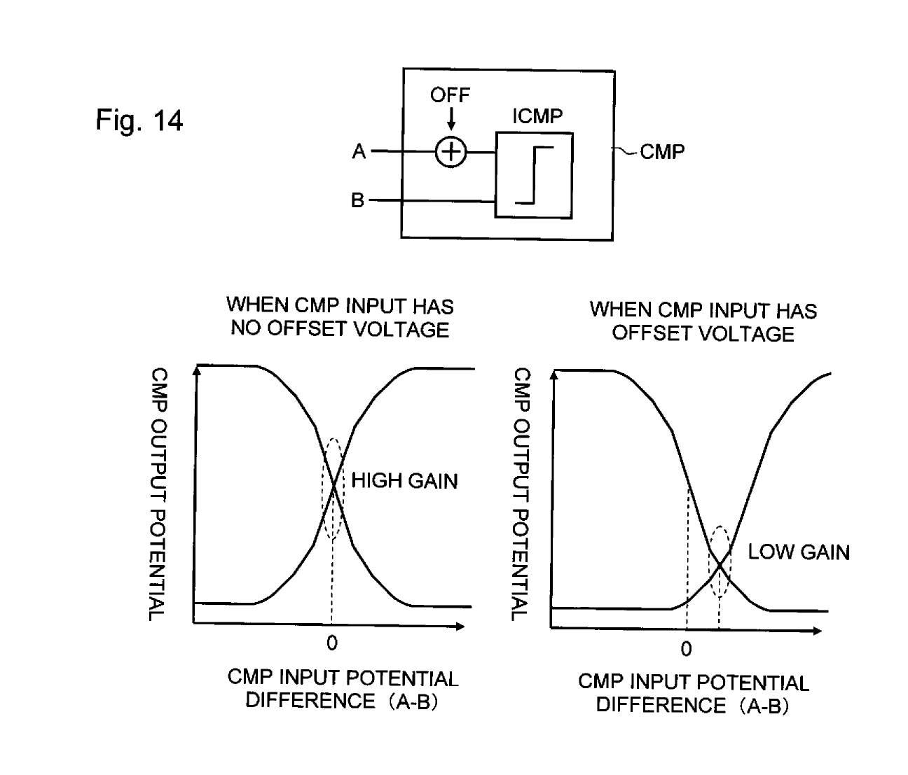

FIG. 14 schematically shows an output of the comparator CMP when the input of the comparator CMP has no offset voltage (ideal comparator), and an output of the comparator CMP when the input of the comparator CMP has an offset voltage. The upper portion of FIG. 14 shows a schematic view of the comparator CMP. Input potentials A and B are applied to the input terminals of the comparator CMP.

The graph on the left side in the lower portion of FIG. 14 shows a case where the input of the comparator CMP has no offset voltage (ideal comparator). The graph on the right side in the lower portion of FIG. 14 shows a case where the input of the comparator CMP has an offset voltage. The horizontal axis of each graph represents an input potential difference (A−B) of the comparator CMP, and the longitudinal axis of each graph represents the output of the comparator CMP. A comparator in which an output voltage at the input potential difference (A−B) that switches from H to L or L to H has a large gradient (high gain) is preferably used because such a comparator has a high accuracy.

When the input of the comparator CMP has no offset voltage, the gain becomes high at the input potential difference (A−B)=0 at which the output signal of the comparator CMP switches. Thus, the comparator CMP has a high accuracy. Meanwhile, when the input of the comparator CMP has an offset voltage, the input potential difference (A−B) at which the output signal of the comparator CMP switches deviates from 0. As a result, the gain becomes lower and the accuracy of the comparator is decreased.

### Second Exemplary Embodiment

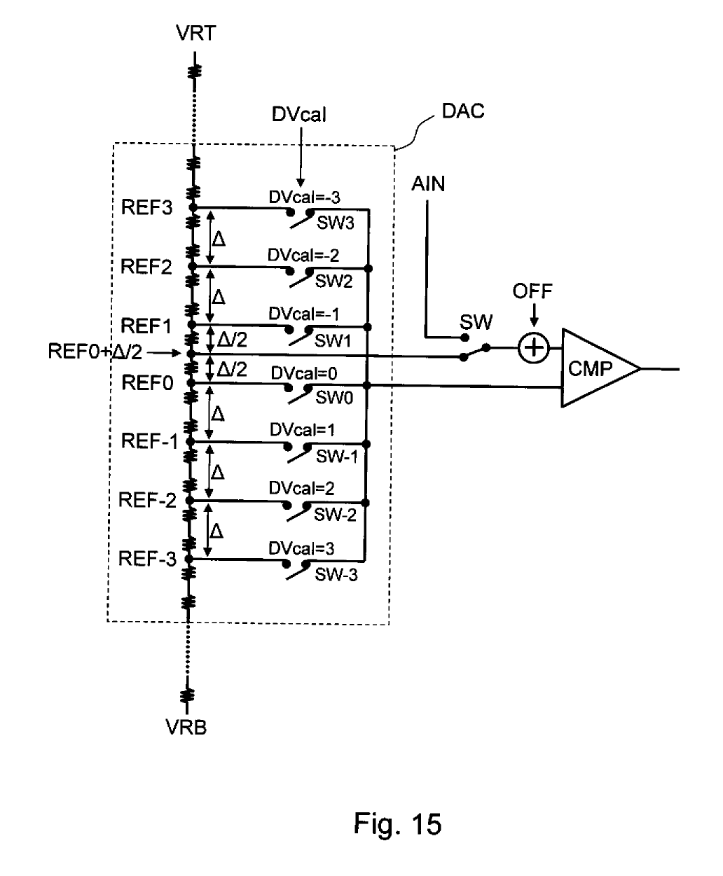

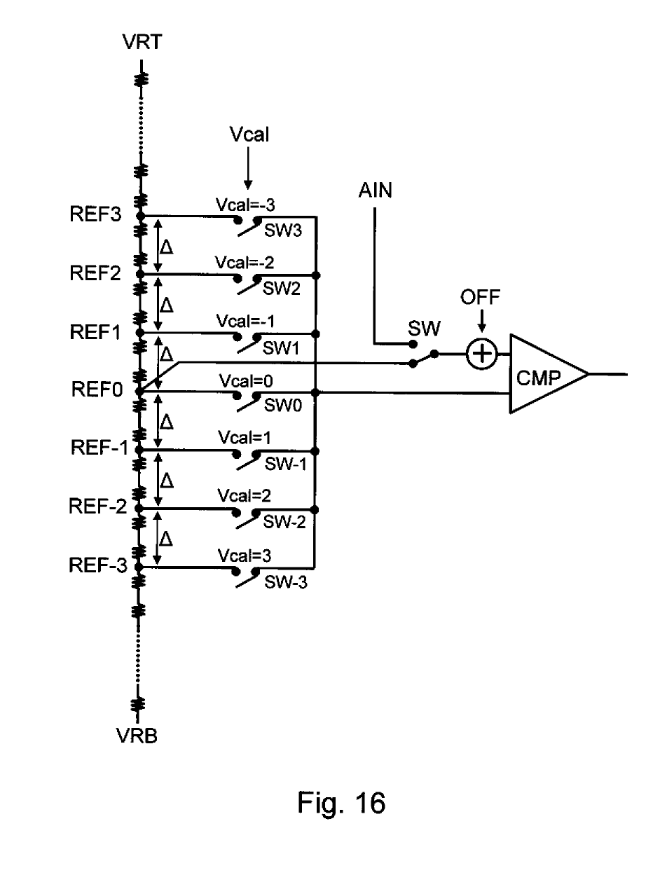

Next, a second exemplary embodiment of the present invention will be described with reference to FIGS. 15 and 16. FIG. 15 is a circuit diagram showing an A/D converter according to the second exemplary embodiment. In the second exemplary embodiment, the digital-analog converter DAC adjusts the reference voltage REF, and also adjusts the offset voltage OFF of the comparator CMP, as with the first exemplary embodiment. In FIG. 15, the offset voltage OFF of the comparator CMP is illustrated outside the comparator CMP for convenience of illustration.

In the A/D converter shown in FIG. 15, between a high-potential power supply VRT and a low-potential power supply VRB, a resistor ladder generates reference voltages REF-1, REF-2, and REF-3 on the negative potential side and reference voltages REF1, REF2, REF3 on the positive potential side, from a default reference voltage REF0 at intervals of Δ. Nodes at which the reference voltages REF-3 to REF3 are generated are connected respectively through switches SW-3 to SW3 to a reference voltage input terminal of the comparator CMP. In the calibration mode, ON/OFF of the switches SW-3 to SW3 is controlled by the digital control signal DVcal.

In the calibration mode, the input terminal for the analog input signal AIN of the comparator CMP is always supplied with REF0+Δ/2 which is shifted from the default reference voltage REF0 to the positive side by Δ/2. The reference voltage input terminal of the comparator CMP is supplied with one of the reference voltages REF-3 to REF3 through one of the switches SW-3 to SW3 selected by the digital control signal DVcal.

When the digital control signal DVcal indicates 3 (DVcal=3), for example, the reference voltage REF-3 is input to the reference voltage input terminal of the comparator CMP. When the digital control signal DVcal indicates 0 (DVcal=0), the reference voltage REF0 is input to the reference voltage input terminal of the comparator CMP. When the digital control signal DVcal indicates −3 (DVcal=−3), the reference voltage REF3 is input to the reference voltage input terminal of the comparator CMP.

In short, when the input potential difference of the comparator CMP in the calibration mode is set to nΔ+Δ/2 (where n is an integer), the final adjusted offset voltage OFFadjf satisfies −Δ/2<OFFadjf≦Δ/2, as with the first exemplary embodiment. Therefore, the same effects as those of the first exemplary embodiment can be obtained.

FIG. 16 is a circuit diagram showing an A/D converter according to a comparative example of the second exemplary embodiment. The A/D converter shown in FIG. 16 differs from that shown in FIG. 15 in that the default reference voltage REF0 is input to a terminal on the analog input signal AIN side in the calibration mode. The other components are the same, so the description thereof is omitted. In the configuration shown in FIG. 16, the final adjusted offset voltage OFFadjf satisfies 0<OFFadjf≦Δ, as with the comparative example of the first exemplary embodiment.

### Third Exemplary Embodiment

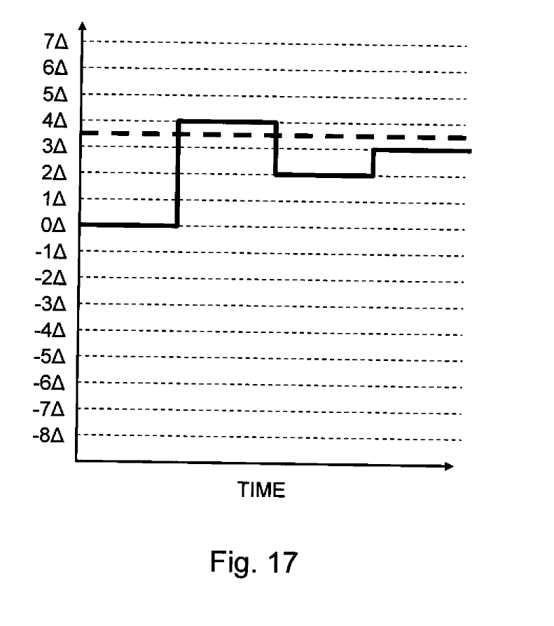

Next, a third exemplary embodiment of the present invention will be described with reference to FIGS. 17 to 19. An A/D converter according to the third exemplary embodiment has the same configuration as that of the first exemplary embodiment. In the first exemplary embodiment, the final calibration voltage Vcalf is searched by using digital control signals of a linear type. Meanwhile, in the third exemplary embodiment, digital control signals of a binary search type are used for search.

FIG. 17 shows a conceptual diagram of 4-bit binary search. The horizontal axis represents time and the longitudinal axis represents signal level. The dashed line indicates a search target signal and the solid line indicates a search signal. As shown in FIG. 17, the magnitude of the search signal is compared with the magnitude of the search target signal, and a search target range is narrowed down to a half of the range for every predetermined number of searches. In the case of N-bit (where N is a natural number) search, for example, N number of searches are required. That is, in the case of 4-bit binary search, four searches are required to complete the search. Meanwhile, in the case of a linear type, 2^{N} number of searches are required at maximum for the N-bit search. That is, the binary search makes it possible to adjust the offset voltage OFF of the comparator CMP for a certain period of time and in a short period of time.

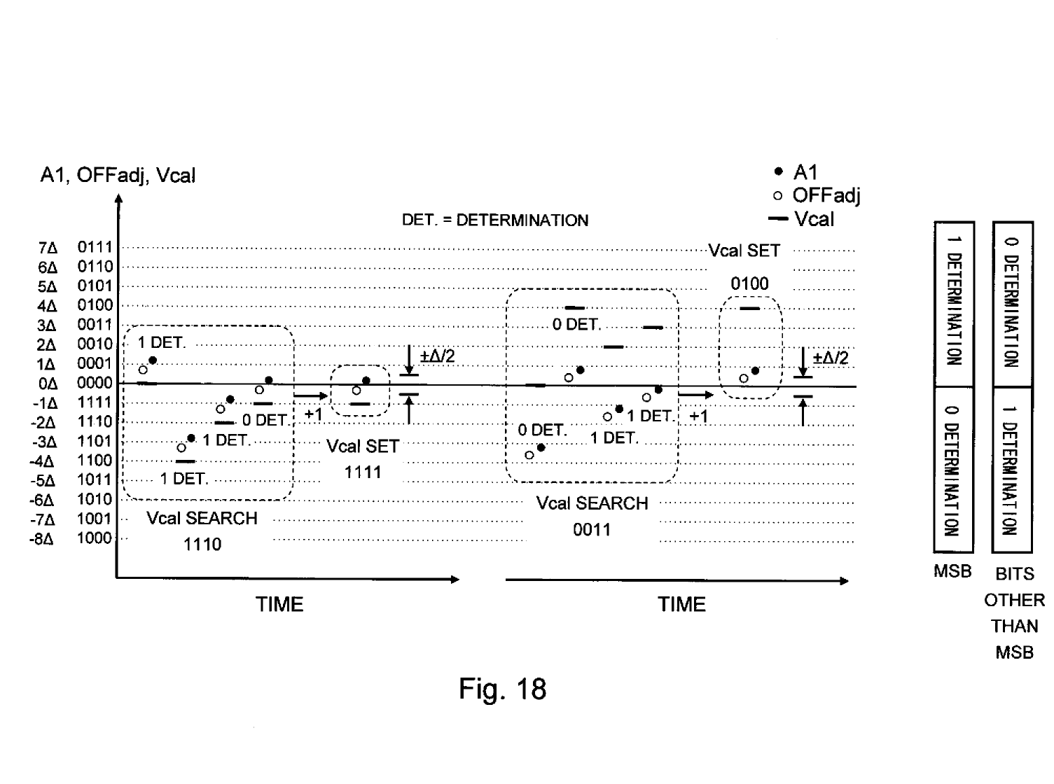

Referring now to FIG. 18, a procedure for the 4-bit binary search at the final calibration voltage Vcalf will be described. Assume that the first bit (MSB) indicates “1” (H: High) when the input potential difference, i.e., the calibration input signal A1 is positive, and indicates “0” (L: Low) when the calibration input signal A1 is negative. Also assume that the subsequent three bits indicate “1” (H: High) when the input potential difference, i.e., the calibration input signal A1 is negative, and indicate “0” (L: Low) when the calibration input signal A1 is positive. After the determination of the final bit is completed, the final calibration voltage Vcalf is generated from a value obtained by adding “1” to the bit string thus obtained.

The graph on the left side of FIG. 18 shows binary search results when the offset voltage OFF of the comparator CMP is 0.8Δ (Δ: the resolution of the digital-analog converter DAC) (offset voltage OFF=0.8Δ). In FIG. 18, “” indicates the calibration input signal A1, “◯” indicates the adjusted offset voltage OFFadj, and “-” indicates the calibration voltage Vcal.

At the first bit (MSB), the calibration voltage Vcal=0 Δ and A1=OFF+Vcal+Δ/2=0.8Δ+Δ/2=1.3Δ. Thus, the output of the comparator CMP is 1. At the subsequent bit, the calibration voltage Vcal=−4Δ and A1=OFF+Vcal+Δ/2=0.8Δ−4Δ+Δ/2=−2.7Δ. Thus, the output of the comparator CMP is 1. Further, at the subsequent bit, the calibration voltage Vcal=−2Δ and A1=OFF+Vcal+Δ/2=0.8Δ−2Δ+Δ/2=−0.7Δ. Thus, the output of the comparator CMP is 1. At the final bit, the calibration voltage Vcal=−Δ and A1=OFF+Vcal+Δ/2=0.8Δ−Δ+Δ/2=0.3Δ. Thus, the output of the comparator CMP is 0.

In sum, the search result for the calibration voltage Vcal is “1110”. Then, when “1” is added to the search result “1110”, “1111” is obtained. Thus, the final calibration voltage Vcalf is set to −Δ (Vcalf=−Δ). As a result, the final adjusted offset voltage OFFadjf=OFF+Vcalf=0.8Δ−Δ=−0.2Δ.

The graph on the right side of FIG. 18 shows a case where the offset voltage OFF of the comparator CMP is −3.8Δ (OFF=−3.8Δ). At the first bit (MSB), the calibration voltage Vcal=0Δ and A1=OFF+Vcal+Δ/2=−3.8Δ+Δ/2=−3.3Δ. Thus, the output of the comparator CMP is 0. At a subsequent bit, the calibration voltage Vcal=4Δ and A1=OFF+Vcal+Δ/2=−3.8Δ+4Δ+Δ/2=0.7Δ. Thus, the output of the comparator CMP is 0. At the subsequent bit, the calibration voltage Vcal=2Δ and A1=OFF+Vcal+Δ/2=−3.8Δ+2Δ+Δ/2=−1.3Δ. Thus, the output of the comparator CMP is 1. At the final bit, the calibration voltage Vcal=3Δ and A1=OFF+Vcal+Δ/2=−3.8Δ+3Δ+Δ/2=−0.3Δ. Thus, the output of the comparator CMP is 1.

That is, the search result for the calibration voltage Vcal is “0011”. When “1” is added to the search result “0011”, “0100” is obtained. Thus, the final calibration voltage Vcalf is set to 4Δ (Vcalf=4Δ). As a result, the final adjusted offset voltage OFFadjf=OFF+Vcalf=−3.8Δ+4Δ=0.2Δ.

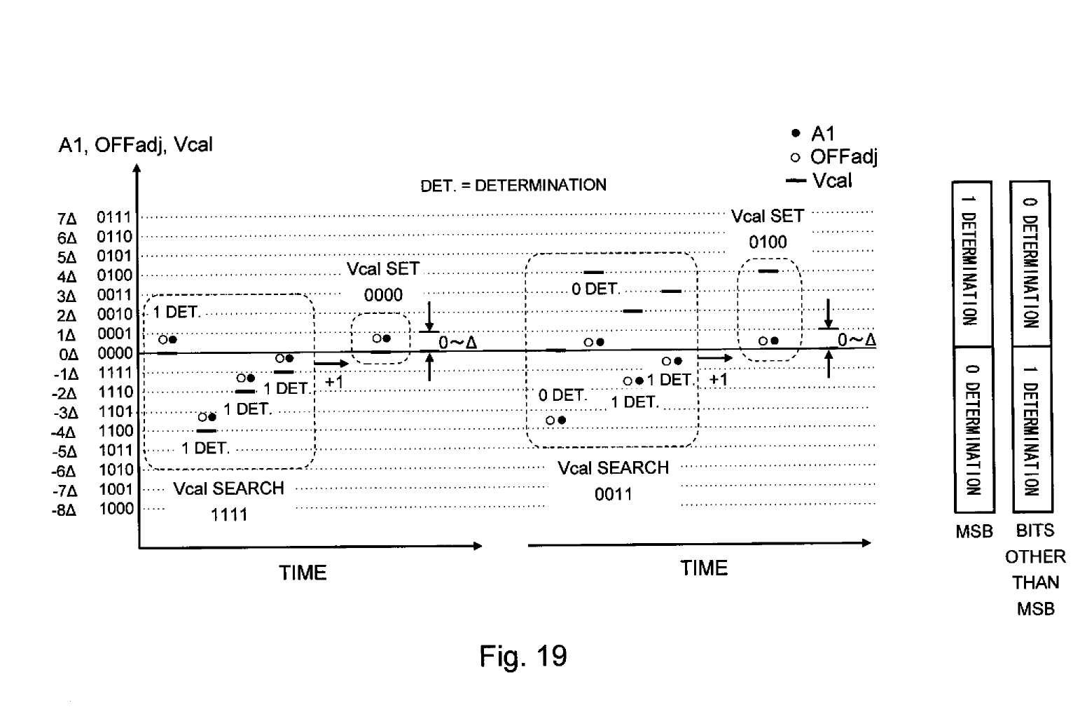

The graph on the left side of FIG. 19 shows a comparative example which indicates results of the binary search when the offset voltage OFF of the comparator CMP is 0.8Δ (OFF=0.8Δ). The configuration of the A/D converter is identical to that of the comparative example of the first exemplary embodiment. In FIG. 19, “” represents the calibration input signal A1, “◯” represents the adjusted offset voltage OFFadj, and “-” represents the calibration voltage Vcal. In the comparative example, A1=OFFadj.

At the first bit (MSB), the calibration voltage Vcal=0Δ and A1=OFF+Vcal=0.8Δ. Thus, the output of the comparator CMP is 1. At a subsequent bit, the calibration voltage Vcal=−4Δ and A1=OFF+Vcal=0.8Δ−4Δ=−3.2Δ. Thus, the output of the comparator CMP is 1. Further, at the subsequent bit, the calibration voltage Vcal=−2Δ and A1=OFF+Vcal=0.8Δ−2Δ=−1.2Δ. Thus, the output of the comparator CMP is 1. At the final bit, the calibration voltage Vcal=−Δ and A1=OFF+Vcal=0.8Δ−Δ=−0.2Δ. Thus, the output of the comparator CMP is 1.

That is, the search result for the calibration voltage Vcal is “1111”. When “1” is added to the search result “1111”, “0000” is obtained. Thus, the final calibration voltage Vcalf is set to 0Δ (Vcalf=0Δ). As a result, the final adjusted offset voltage OFFadjf=OFF+Vcalf=0.8Δ.

The graph on the right side of FIG. 19 shows a case where the offset voltage OFF of the comparator CMP is −3.8Δ (OFF=−3.8Δ). At the first bit (MSB), the calibration voltage Vcal=0Δ and A1=OFF+Vcal=−3.8Δ. Thus, the output of the comparator CMP is 0. At the subsequent bit, the calibration voltage Vcal=4Δ and A1=OFF+Vcal=−3.8Δ+4Δ=0.2Δ. Thus, the output of the comparator CMP is 0. Further, at the subsequent bit, the calibration voltage Vcal=2Δ and A1=OFF+Vcal+Δ/2=−3.8Δ+2Δ=−1.8Δ. At the final bit, the calibration voltage Vcal=3Δ and A1=OFF+Vcal+Δ/2=−3.8Δ+3Δ=−0.8Δ, Thus, the output of the comparator CMP is 1.

That is, the search result for the calibration voltage Vcal is “0011”. When “1” is added to the search result “0011”, “0100” is obtained. Thus, the final calibration voltage Vcalf is set to 4Δ (Vcalf=4Δ). As a result, the final adjusted offset voltage OFFadjf=OFF+Vcalf=−3.8Δ+4Δ=0.2Δ.

In the above comparative example, the final adjusted offset voltage OFFadjf satisfies 0<OFFadjf≦Δ, as with the comparative example of the first exemplary embodiment. Meanwhile, in the third exemplary embodiment, the final adjusted offset voltage OFFadjf satisfies −Δ/2<OFFadjf≦Δ/2, as with the first exemplary embodiment. Accordingly, the same effects as those of the first exemplary embodiment can be obtained.

Note that linear type search may be combined with binary search. Particularly, it is preferable that, the linear type search be performed at the subsequent stage after completion of the binary search at the pre-stage.

### Fourth Exemplary Embodiment

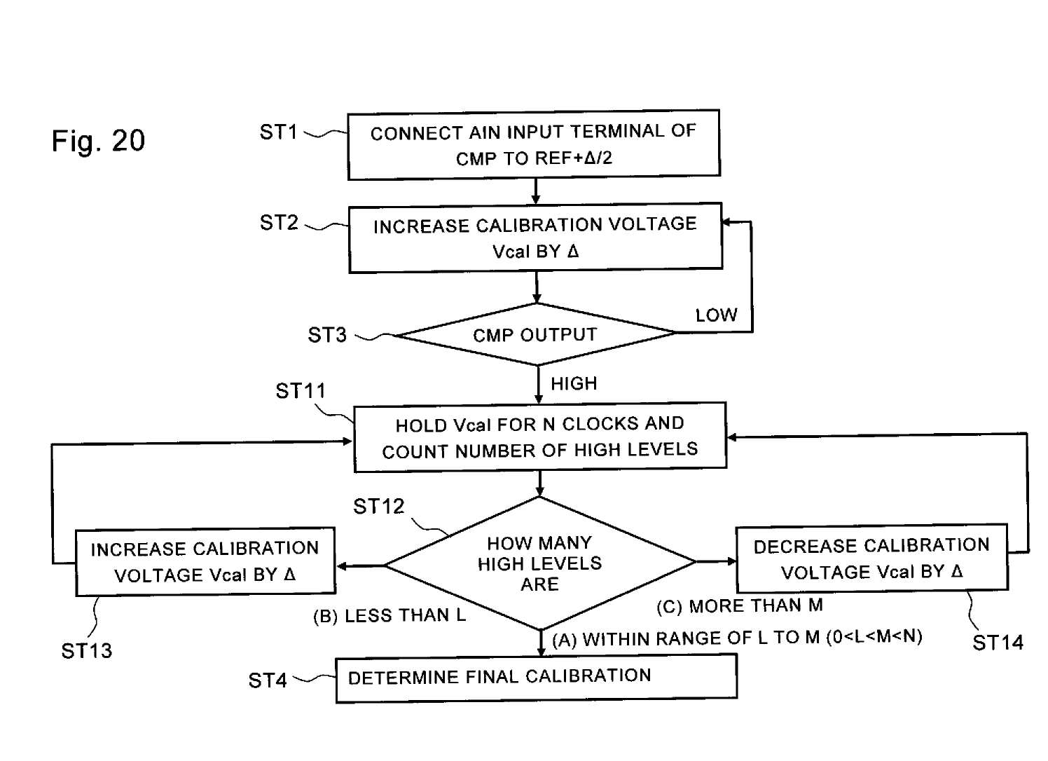

Next, a forth exemplary embodiment of the present invention will be described with reference to FIG. 20. FIG. 20 is a flowchart showing a calibration method according to the fourth exemplary embodiment. Steps ST1 to ST3 are the same as those in the flowchart of the calibration method according to the first exemplary embodiment shown in FIG. 5, so the description thereof is omitted. In the calibration method shown in FIG. 5, when the output of the comparator CMP becomes H (High), the final calibration voltage Vcalf is determined and the calibration is completed. Meanwhile, in the calibration method according to the fourth exemplary embodiment, when the output of the comparator CMP becomes H, the calibration voltage Vcal is held for N (N is a natural number) clocks, and the number of levels H is counted (ST11).

When the number of levels H in the output of the comparator CMP is in the range of L to M (L and M are natural numbers) ((A) in ST12), the final calibration voltage Vcalf is determined and the calibration is completed (ST4). Assume herein that 0<L<M<N. When the number of H levels in the output of the comparator CMP is less than L ((B) in ST12), the calibration voltage Vcal is further increased by the resolution Δ of the digital-analog converter DAC, and the process returns to step ST11 (ST13). When the number of H levels in the output of the comparator CMP is more than M ((C) in ST12), the calibration voltage Vcal is decreased by Δ, and the process returns to step ST11 (ST14).

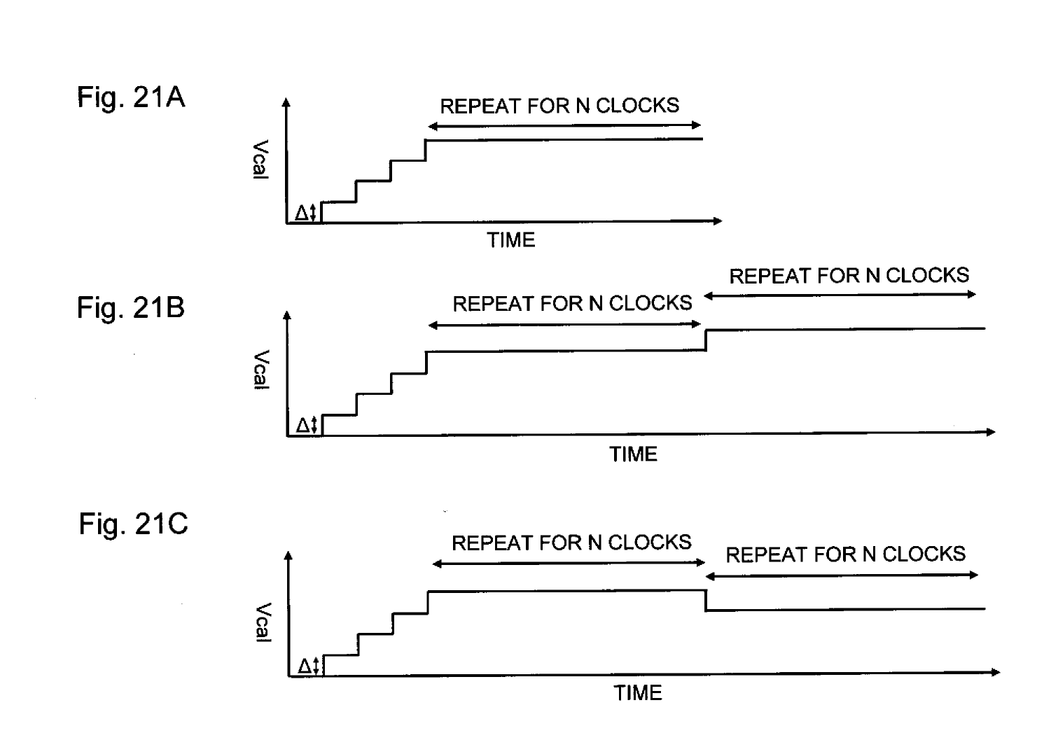

FIGS. 21A, 21B, and 21C are graphs respectively corresponding to (A) in step ST12, (B) in step ST12, and (C) in step ST12. The horizontal axis represents time and the longitudinal axis represents the calibration voltage Vcal. In each of FIGS. 21A, 21B, and 21C, the calibration voltage Vcal is increased by Δ for each clock until the output of the comparator CMP becomes H. When the output of the comparator CMP becomes H, the calibration voltage Vcal is held for N clocks, and the number of H levels is counted. In the case of (A) in step ST12 shown in FIG. 21A, the final calibration voltage Vcalf is determined and the calibration is completed. In the case of (B) in step ST12 shown in FIG. 21B, the calibration voltage Vcal is increased by Δ, the calibration voltage Vcal is held again for N clocks, and the number of H levels is counted. In the case of (C) in step ST12C shown in FIG. 21C, the calibration voltage Vcal is decreased by Δ, the calibration voltage Vcal is held again for N clocks, and the number of H levels is counted.

The calibration method according to the fourth exemplary embodiment is especially effective for use in a noisy environment. On the other hand, in a less noisy environment, (C) in step ST12 may be omitted. Then, when the number of H levels in the output of the comparator CMP becomes equal to or greater than L, the final calibration voltage Vcalf is determined and the calibration may be completed.

### Fifth Exemplary Embodiment

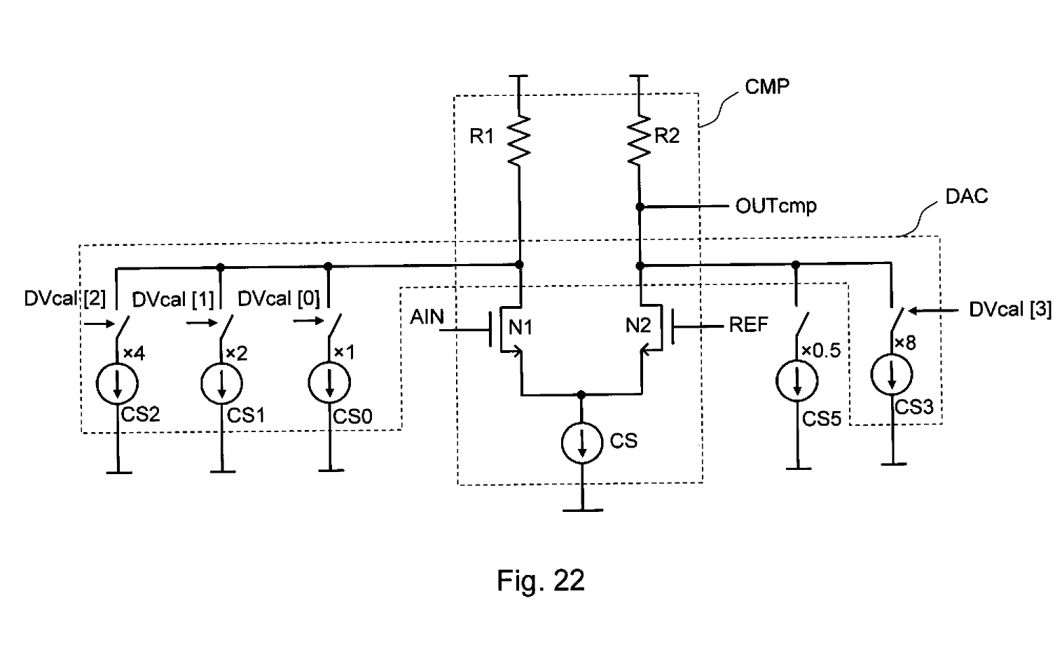

Next, a fifth exemplary embodiment of the present invention will be described with reference to FIG. 22. FIG. 22 is a circuit diagram showing specific examples of the comparator CMP and the digital-analog converter DAC according to the fifth exemplary embodiment. In addition to the components shown in FIG. 4, a current source CS5 that generates Δ/2, which is a half of the resolution Δ of the digital-analog converter DAC, is connected to an output node of the comparator CMP. Specifically, assuming that the amount of current generated by the current source CS0 is 1, the amount of current generated by the current source CS5 is ½. One end of the current source CS5 is grounded. The other end of the current source CS5 is connected to a node (output node) between the load resistor R2 and the NMOS transistor N2 through a switch.

In the fifth exemplary embodiment, two input terminals of the comparator CMP are short-circuited in the calibration mode. In the calibration mode, the switch of the current source CS5 is always off, and the final calibration voltage Vcalf is determined. After that, the switch of the current source CS5 is turned on. Alternatively, in the calibration mode, the switch of the current source CS5 is always on, and the final calibration voltage Vcalf is determined. Then, in the normal mode, the switch of the current source CS5 may be turned off. Thus, the final adjusted offset voltage OFFadjf satisfies −Δ/2<OFFadjf≦Δ/2, as with the first exemplary embodiment. Therefore, the same effects as those of the first exemplary embodiment can be obtained.

### Sixth Exemplary Embodiment

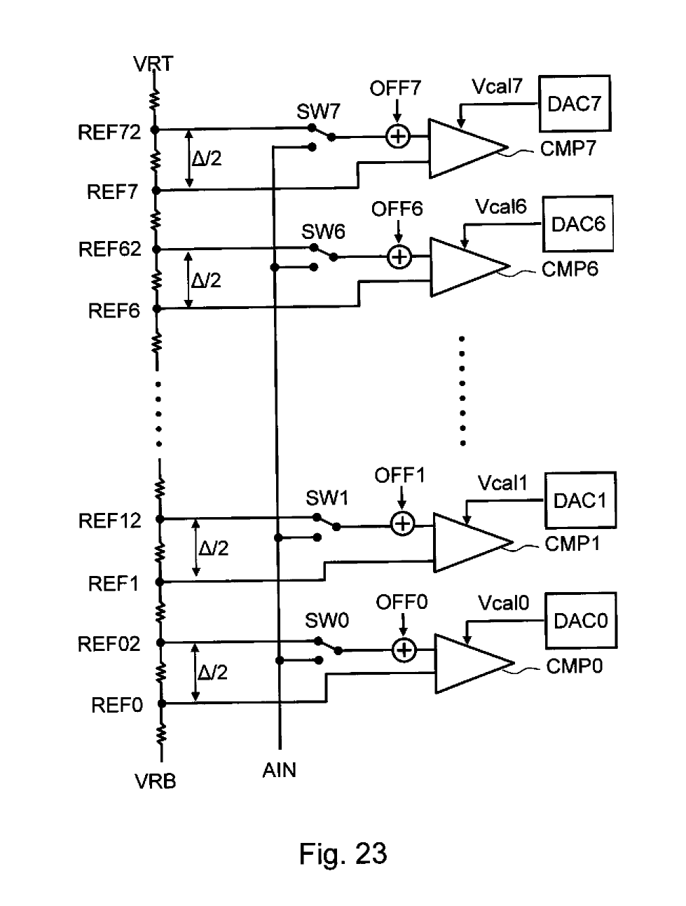

Next, a sixth exemplary embodiment of the present invention will be described with reference to FIG. 23. FIG. 23 is a circuit diagram showing a parallel A/D converter according to the sixth exemplary embodiment. The parallel A/D converter according to the sixth exemplary embodiment includes eight sets of comparators CMP0 to CMP7 and digital-analog converters DAC0 to DAC7. In FIG. 23, the offset voltages OFF of the comparators CMP0 to CMP7 are illustrated outside the comparators CMP0 to CMP7 for convenience of illustration. Further, the number of each of the comparators and digital-analog converters is not limited to eight.

Between the high-potential power supply VRT and the low-potential power supply VRB, a resistor ladder generates reference voltages REF1 to REF7 in the order from the reference voltage REF0 to the positive potential side at predetermined intervals. Nodes at which the reference voltages REF0 to REF7 are generated are respectively connected to the reference voltage input terminals of the comparators CMP0 to CMP7. Meanwhile, in the calibration mode, the input terminals for the analog input signal AIN of the comparators CMP0 to CMP7 are supplies with calibration reference voltages REF02 to REF72, which are obtained by adding Δ/2 (Δ: the resolution of the digital-analog converters DAC0 to DAC7) to each of the reference voltages REF0 to REF7, by switching switches SW0 to SW7.

In the sixth exemplary embodiment, when the input potential difference of each of the comparators CMP0 to CMP7 in the calibration mode is set to Δ/2, as with the first exemplary embodiment, the final adjusted offset voltage OFFadjf satisfies −Δ/2<OFFadjf≦Δ/2. That is, the absolute value of the final adjusted offset voltage OFFadjf can be halved without changing the resolution Δ of the digital-analog converters DAC0 to DAC7. Consequently, a highly accurate A/D converter can be provided. Moreover, in the parallel A/D converter according to the sixth exemplary embodiment, the average value of the offset voltage can be theoretically set to 0. Therefore, a highly accurate A/D converter having no systematic offset can be provided.

### Seventh Exemplary Embodiment

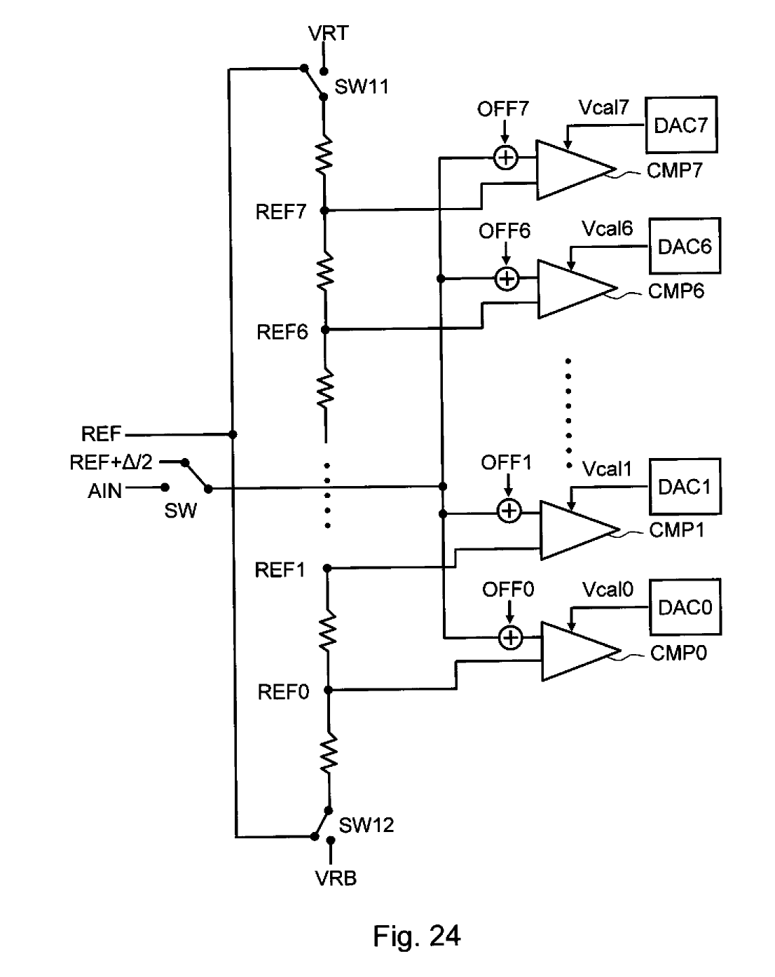

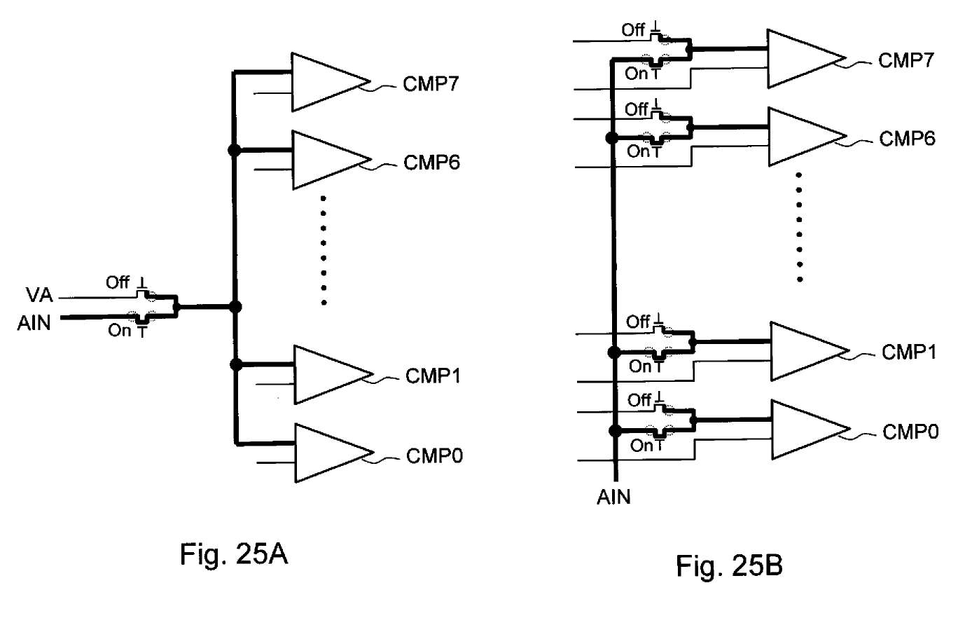

Next, a seventh exemplary embodiment of the present invention will be described with reference to FIGS. 24, 25A, and 25B. FIG. 24 is a circuit diagram showing a parallel A/D converter according to the seventh exemplary embodiment. The parallel A/D converter according to the seventh exemplary embodiment includes eight sets of the comparators CMP0 to CMP7 and the digital-analog converters DAC0 to DAC7, as with the parallel A/D converter according to the sixth exemplary embodiment shown in FIG. 23. Also in FIG. 24, the offset voltages OFF of the comparators CMP0 to CMP7 are illustrated outside the comparators CMP0 to CMP7 for convenience of illustration. Further, the number of each of the comparators and digital-analog converters is not limited to eight.

In the sixth exemplary embodiment, the switches SW0 to SW7 are respectively connected to the input terminals for the analog input signal AIN of the comparators CMP0 to CMP7. Meanwhile, in the seventh exemplary embodiment, the input terminals for the analog input signal AIN of the comparators CMP0 to CMP7 are commonly connected to the switch SW. That is, the switches SW0 to SW7 according to the sixth exemplary embodiment are combined in the switch SW. Further, switches SW11 and SW12 are provided at both ends of a resistor ladder. Specifically, the switch SW11 has one end connected to the high-potential power supply VRT, and the other end connected to the resistor ladder. The switch SW12 has one end connected to the low-potential power supply VRB, and the other end connected to the resistor ladder. The other components are similar to those of the sixth exemplary embodiment, so the description thereof is omitted. The same effects can also be obtained by providing only one of the switches SW11 and SW12.

The switches SW11 and SW12 are respectively connected to the high-potential power supply VRT and the low-potential power supply VRB in the normal mode. Meanwhile, in the calibration mode, when both the switches SW11 and SW12 are connected to the reference potential REF, the reference voltage REF is commonly supplied to the reference voltage input terminals of the comparators CMP0 to CMP7. Further, the calibration reference voltage REF+Δ/2, which is obtained by adding Δ/2 (Δ: the resolution of the digital-analog converts DAC0 to DAC7) to the reference voltage REF, is commonly supplied to the input terminals on the analog input signal AIN side of the comparators CMP0 to CMP7, by switching the switch SW.

In the seventh exemplary embodiment, when the input potential difference of each of the comparators CMP0 to CMP7 in the calibration mode is set to Δ/2, as with the first exemplary embodiment, the final adjusted offset voltage OFFadjf satisfies −Δ/2<OFFadjf≦Δ/2. That is, the absolute value of the final adjusted offset voltage OFFadjf can be halved without changing the resolution Δ of the digital-analog converters DAC0 to DAC7. Consequently, a more accurate A/D converter can be provided. Moreover, in the parallel A/D converter according to the seventh exemplary embodiment, the average value of the offset voltage can be theoretically set to 0. Therefore, a highly accurate A/D converter having no systematic offset can be provided.

FIG. 25A schematically shows a connection state in the normal mode according to the seventh exemplary embodiment. FIG. 25B schematically shows a connection state in the normal mode according to the sixth exemplary embodiment. Comparing FIGS. 25A and 25B, it is obvious that in the seventh exemplary embodiment, the number of capacitors connected to the analog input signal AIN is small (as indicated by the dotted lines in FIGS. 25A and 25B). Therefore, deterioration in accuracy due to an increased in input capacitance and parasitic capacitance caused by inserting a switch for adjusting an offset voltage of a comparator can be prevented.

The first to seventh exemplary embodiments can be combined as desirable by one of ordinary skill in the art.

While the invention has been described in terms of several exemplary embodiments, those skilled in the art will recognize that the invention can be practiced with various modifications within the spirit and scope of the appended claims and the invention is not limited to the examples described above.

Further, the scope of the claims is not limited by the exemplary embodiments described above.

Furthermore, it is noted that, Applicant's intent is to encompass equivalents of all claim elements, even if amended later during prosecution.

What is claimed is:

1. An analog-digital converter circuit having a normal mode for converting a received analog signal into a digital signal, and a calibration mode for adjusting an offset voltage of a comparator, the analog-digital converter comprising:
a first comparator having a first analog signal input terminal supplied with an analog signal, and a first reference signal input terminal supplied with a first reference signal, in the normal mode; and
a first calibration circuit that adjusts an offset voltage of the first comparator,
wherein, in the calibration mode, assuming that a calibration resolution of the first calibration circuit is Δ₁, a potential difference between a reference signal supplied to the first analog signal input terminal and a reference signal supplied to the first reference signal input terminal is n₁Δ₁+Δ₁/2 (where n₁ is an integer).

2. The analog-digital converter circuit according to claim 1, wherein the first calibration circuit comprises a digital-analog converter circuit.

3. The analog-digital converter circuit according to claim 1, further comprising:
a second comparator having a second analog signal input terminal supplied with the analog signal, and a second reference signal input terminal supplied with a second reference signal that is different from the first reference signal, in the normal mode; and
a second calibration circuit that adjusts an offset voltage of the second comparator,
wherein, in the calibration mode, assuming that a calibration resolution of the second calibration circuit is Δ₂, a potential difference of a reference signal supplied to the second analog signal input terminal and a reference signal supplied to the second reference signal input terminal is n₂Δ₂+Δ₂/2 (where n₂ is an integer).

4. The analog-digital converter circuit according to claim 3, wherein the second calibration circuit comprises a digital-analog converter circuit.

5. The analog-digital converter circuit according to claim 3, wherein, in the calibration mode, the first and second reference signals are calibrated to adjust offset voltages of the first and second comparators.

6. The analog-digital converter circuit according to claim 3, further comprising:
a first mode selection switch connected to the first analog signal input terminal; and
a second mode selection switch connected to the second analog signal input terminal.

7. The analog-digital converter circuit according to claim 6, wherein the first mode selection switch and the second mode selection switch are combined in a single switch.

8. An analog-digital converter circuit having a normal mode for converting a received analog signal into a digital signal, and a calibration mode for adjusting an offset voltage of a comparator, the analog-digital converter circuit comprising:
a first comparator having a first analog signal input terminal supplied with an analog signal, and a first reference signal input terminal supplied with a first reference signal, in the normal mode; and
a first calibration circuit that adjusts an offset voltage of the first comparator,
wherein the first calibration circuit comprises:
a first main calibration unit that adjusts an offset adjustment amount so that an adjusted offset voltage has a value in a range of 0 to Δ₁ (where Δ₁ is a calibration resolution of the first calibration circuit); and
a first fine adjustment unit that shifts the offset adjustment amount by Δ₁/2.

9. The analog-digital converter circuit according to claim 8, wherein the first calibration circuit comprises a digital-analog converter circuit.

10. The analog-digital converter circuit according to claim 8, wherein, in the calibration mode, the first analog signal input terminal and the first reference signal input terminal are short-circuited.

11. The analog-digital converter circuit according to claim 8, further comprising:
a second comparator having a second analog signal input terminal supplied with an analog signal, and a second reference signal input terminal supplied with a second reference signal that is different from the first reference signal, in the normal mode; and
a second calibration circuit that adjusts an offset voltage of the second comparator,
wherein the second calibration circuit comprises:
a second main calibration unit that adjusts an offset adjustment amount so that an adjusted offset voltage has a value in a range of 0 to Δ₂ (where Δ₂ is a calibration resolution of the second calibration circuit); and
a second fine adjustment unit that shifts the offset adjustment amount by Δ₂/2.

12. The analog-digital converter circuit according to claim 11, wherein the second calibration circuit comprises a digital-analog converter circuit.

13. The analog-digital converter circuit according to claim 11, wherein, in the calibration mode, the second analog signal input terminal and the second reference signal input terminal are short-circuited.

14. A calibration method that adjusts an offset voltage of a comparator by a calibration circuit having a calibration resolution A, the calibration method comprising:
fixing a potential difference applied to two input terminals of the comparator to nΔ+Δ/2 (where n is an integer);
changing a calibration signal supplied to the comparator from the calibration circuit; and
determining an offset adjustment amount based on an output signal output from the comparator.

15. The calibration method according to claim 14, wherein the calibration signal is generated by linear search.

16. The calibration method according to claim 14, further comprising:
holding, when the output signal from the comparator switches from a first level to a second level, a value of the calibration signal for a predetermined period of time, and counting the number of output signals having the second level; and
determining the offset adjustment amount based on the number of output signals.

17. The calibration method according to claim 14, wherein the calibration signal is generated by binary search.

18. A calibration method that adjusts an offset voltage of a comparator by a calibration circuit having a calibration resolution A, the calibration method comprising:
causing two input terminals of the comparator to be short-circuited;
changing a calibration signal supplied to the comparator from the calibration circuit;
determining an offset adjustment amount based on an output signal output from the comparator; and
shifting the determined offset adjustment amount by Δ/2.

19. The calibration method according to claim 18, wherein the calibration signal is generated by linear search.

20. The calibration method according to claim 18, further comprising:
holding, when the output signal from the comparator changes from a first level to a second level, a value of the calibration signal for a predetermined period of time, and counting the number of output signals having the second level; and
determining the offset adjustment amount based on the number of output signals.

21. The calibration method according to claim 18, wherein the calibration signal is generated by binary search.
